(19) United States
(12) Patent Application Publication
(10) Pub. No.: US 2021/0010761 A1
(43) Pub. Date: Jan. 14, 2021

(54) HEAT SINK

(71) Applicant: FURUKAWA ELECTRIC CO., LTD., Tokyo (JP)

(72) Inventors: Masato WATANABE, Tokyo (JP); Masahiro MEGURO, Tokyo (JP); Hiroshi SAKAI, Tokyo (JP); Yasuhiro UCHIMURA, Tokyo (JP); Shuta HIKICHI, Tokyo (JP)

(73) Assignee: FURUKAWA ELECTRIC CO., LTD., Tokyo (JP)

(21) Appl. No.: 17/035,509

(22) Filed: Sep. 28, 2020

Related U.S. Application Data
(63) Continuation of application No. PCT/JP2019/013928, filed on Mar. 29, 2019.

(30) Foreign Application Priority Data
Mar. 30, 2018 (JP) 2018-068298

(51) Int. Cl. F28F 3/04; F28D 15/02

(52) U.S. Cl. CPC F28F 3/04; F28D 15/0275

(57) ABSTRACT

The heat sink includes a radiation fin extending in a vertical direction from a heat-receiving unit, in which the radiation fin includes a notched portion in which a tip end side corner of the radiation fin is retracted inward in a main surface direction of the radiation fin with respect to a virtual rectangle or a virtual square formed of a side of the radiation fin on the heat-receiving unit side viewed from the main surface side, a first side extending from both ends of the side on the heat-receiving unit side in a direction orthogonal to the side on the heat-receiving unit side and a second side formed by extending a linear portion on the side of the radiation fin on a tip end side facing the side on the heat-receiving unit side to the first side.

### CROSS REFERENCE TO RELATED APPLICATIONS

The present application is a continuation application of International Patent Application No. PCT/JP2019/013928 filed on Mar. 29, 2019, which claims the benefit of Japanese Patent Application No. 2018-068298, filed on Mar. 30, 2018. The contents of these applications are incorporated herein by reference in their entirety.

### BACKGROUND

### Technical Field

The present disclosure relates to a heat sink that cools a heating element such as an electronic part.

### Background

As electronic apparatuses are provided with increasingly higher functions, heating elements such as electronic parts are incorporated in electronic apparatuses at high density. Heat sinks may be used as units configured to cool heating elements such as electronic parts. Forced air cooling using a ventilating fan or the like is applied to the heat sinks. That is, cooling performance of the heat sinks may be demonstrated by supplying cooling air to the heat sinks.

As an example of the above-described heat sinks, a heat sink is proposed, which includes a heat-receiving member that receives heat of a heating component, a plurality of radiation fins installed on the heat-receiving member and a cover member that covers the plurality of radiation fins, in which flow paths through which a fluid such as a gas flows are formed between respective radiation fins (Japanese Patent Laid-Open No. 2016-207928). The heat sink according to Japanese Patent Laid-Open No. 2016-207928 is designed to improve cooling performance of the heat sink by reducing a temperature difference in a length direction among the flow paths formed in the heat sink through which the fluid flows.

However, according to Japanese Patent Laid-Open No. 2016-207928, a pressure difference, that is, a pressure loss may be generated in cooling air supplied to the heat sink between a windward side and a leeward side of the heat sink. The pressure difference generated in the cooling air may cause an increase in ventilation resistance of the cooling air supplied to the heat sink. An increase in the ventilation resistance of the cooling air may cause an increase in power consumption of the ventilating fan to supply a necessary amount of cooling air to the heat sink or may require the size of the ventilating fan to be increased, making it impossible to mount the heat sink in a small space.

On the other hand, in order to reduce the ventilation resistance of the heat sink, if the number of radiation fins to be installed is reduced or the size of the radiation fins such as width, height, and thickness is reduced, cooling performance of the heat sink deteriorates.

The present disclosure is related to providing a heat sink capable of reducing pressure loss by preventing an increase in ventilation resistance of cooling air while obtaining excellent cooling performance.

### SUMMARY

A first aspect of the present disclosure is a heat sink including a radiation fin extending in a vertical direction from a heat-receiving unit, in which the radiation fin includes a notched portion in which a tip end side corner of the radiation fin is retracted inward in a main surface direction of the radiation fin with respect to a virtual rectangle or a virtual square formed of a side of the radiation fin on the heat-receiving unit side viewed from the main surface side, a first side extending from both ends of the side on the heat-receiving unit side in a direction orthogonal to the side on the heat-receiving unit side and a second side formed by extending a linear portion on the side of the radiation fin on a tip end side facing the side on the heat-receiving unit side to the first side.

Another aspect of the present disclosure is a heat sink in which the notched portion has a C chamfer shape, an R chamfer shape or a combination of a C chamfer shape and an R chamfer shape.

A further aspect of the present disclosure is a heat sink in which a ratio of a dimension of the notched portion in the first side direction to a length of the first side of the virtual rectangle or the virtual square is 30% to 100%.

A further aspect of the present disclosure is a heat sink, in which an area ratio of the main surface of the radiation fin to an area of the virtual rectangle or the virtual square is 50% to 98%.

A further aspect of the present disclosure is a heat sink in which the notched portion has an R chamfer shape.

A further aspect of the present disclosure is a heat sink in which a radius of curvature of the R chamfer shape is 5 mm or more.

A further aspect of the present disclosure is a heat sink in which the notched portions are provided at both corners on the tip end side of the radiation fin.

A further aspect of the present disclosure is a heat sink in which the notched portion is provided at a corner farther from a heating element thermally connected to the heat-receiving unit of both corners on the tip end side of the radiation fin.

A further aspect of the present disclosure is a heat sink further including a heat-receiving plate in which the radiation fin extends in the vertical direction from the heat-receiving plate.

A further aspect of the present disclosure is a heat sink further including a heat pipe.

A further aspect of the present disclosure is a heat sink in which the notched portion is provided at a corner farther from a heating element and the heat pipe thermally connected to the heat-receiving unit of both corners on the tip end side of the radiation fin.

According to the aspect of the present disclosure, instead of the virtual rectangle or virtual square, the tip end side corner of the radiation fin includes the notched portion retracted inward in the main surface direction of the radiation fin, and so ventilation resistance of cooling air circulating between the radiation fins of the heat sink decreases and pressure loss of the cooling air decreases. Therefore, it is possible to prevent power consumption of the ventilating fan from increasing, which contributes to energy saving and allows the ventilating fan to be downsized, and thus the heat sink can be mounted even in a small space. According to the aspect of the present disclosure, it is possible to reduce pressure loss of the cooling air and thus obtain excellent cooling performance. The tip end side of the radiation fins has less contribution to heat dissipation than the proximal end side close to the heat-receiving unit, whereas according to the aspect of the present disclosure, the notched portion is provided on the tip end side of the radiation fins, and so it is possible to maintain excellent cooling performance.

According to the aspect of the present disclosure, since the notched portion has a C chamfer shape, an R chamfer shape or a combination of a C chamfer shape and an R chamfer shapes, it is possible to reliably reduce ventilation resistance of the cooling air circulating between the radiation fins of the heat sink.

According to the aspect of the present disclosure, since the ratio of the dimension of the notched portion in the first side direction to the length of the first side of the virtual rectangle or virtual square is 30% to 100%, it is possible to more smoothly circulate the cooling air between the radiation fins, and as a result, more reliably reduce ventilation resistance.

According to the aspect of the present disclosure, since the area ratio of the main surface of the radiation fin to the area of the virtual rectangle or virtual square is 50% to 98%, it is possible to realize an improvement in the cooling performance and a reduction in pressure loss of the cooling air in well-balanced manner.

According to the aspect of the present disclosure, since the notched portion has an R chamfer shape, it is possible to reliably reduce ventilation resistance of the cooling air circulating between the radiation fins of the heat sink while reliably maintaining excellent cooling performance.

### BRIEF DESCRIPTION OF THE DRAWINGS

FIG. 1 is a perspective view of a heat sink according to a first exemplary embodiment of the present disclosure.

FIG. 2 is a side view describing the heat sink according to the first exemplary embodiment of the present disclosure.

FIG. 3 is a front view illustrating a state in which a heating element is thermally connected to the heat sink according to the first exemplary embodiment of the present disclosure.

FIG. 4 is a bottom view illustrating a state in which a heating element is thermally connected to the heat sink according to the first exemplary embodiment of the present disclosure.

FIG. 5 is a perspective view of a heat sink according to a second exemplary embodiment of the present disclosure.

FIG. 6 is a side view describing the heat sink according to the second exemplary embodiment of the present disclosure.

FIG. 7A is a bottom view of a heat sink according to a third exemplary embodiment of the present disclosure and FIG. 7B is a side view of the heat sink according to the third exemplary embodiment of the present disclosure.

FIGS. 8A to 8D are each a diagram illustrating notched portions of radiation fins according to other embodiments.

### DETAILED DESCRIPTION

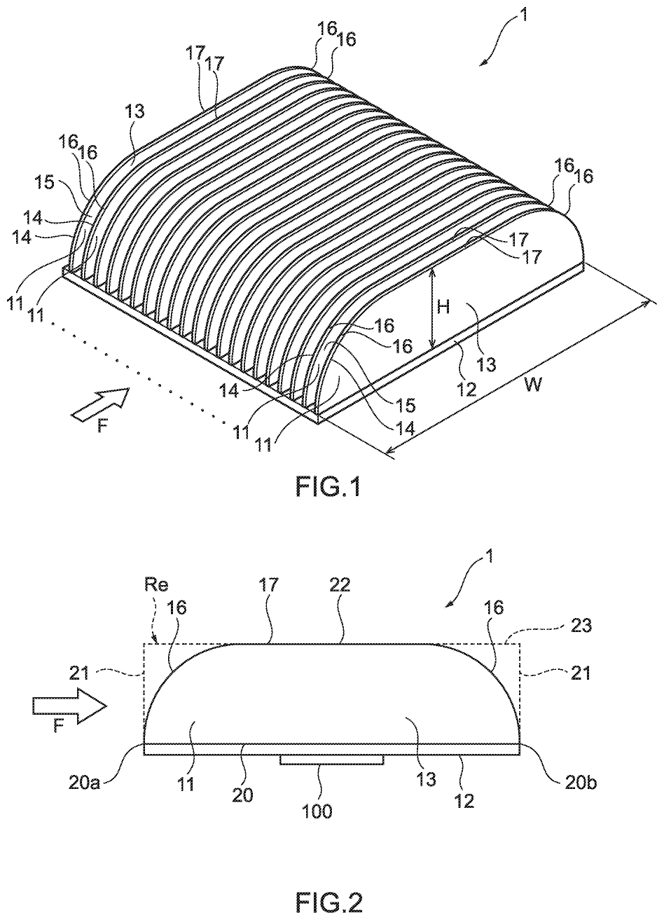

Hereinafter, a heat sink according to a first exemplary embodiment of the present disclosure will be described using the accompanying drawings. As shown in FIGS. 1 and 2, a heat sink 1 according to the first exemplary embodiment is provided with a flat plate-shaped heat-receiving plate 12, and a plurality of radiation fins 11, 11, 11 . . . provided upright on the heat-receiving plate 12. With the radiation fins 11 attached to the heat-receiving plate 12, the radiation fins 11 are thermally connected to the heat-receiving plate 12. The radiation fins 11 extend in the vertical direction with respect to the heat-receiving plate 12. Each radiation fin 11 is thin, flat plate-shaped and includes both main surfaces 13 and a side face 14 that connects both main surfaces 13. In the radiation fin 11, the main surfaces 13 mainly contribute to heat dissipation of the radiation fin 11. A width of the side face 14 forms a thickness of the radiation fin 11.

The radiation fins 11 are arranged in parallel to a direction substantially orthogonal to the extending direction of the main surface 13. Furthermore, the radiation fins 11 are arranged so that the main surface 13 of each radiation fin 11 is aligned substantially parallel to the main surface 13 of another adjacent radiation fin 11. Therefore, a space 15 is formed between the main surfaces 13 of the adjacent radiation fins 11.

A width (W) of the radiation fin 11 corresponds to a width of the heat-receiving plate 12 and the plurality of radiation fins 11, 11, 11 . . . forming the heat sink 1 are arranged in parallel from one end to another end of the heat-receiving plate 12 at substantially equal intervals. In the heat sink 1, a dimension of the radiation fin 11 in the width (W) direction and a dimension in the height (H) direction are different.

With cooling air F supplied from a ventilation fan (not shown) to the heat sink 1, the heat sink 1 can demonstrate excellent cooling performance. The cooling air F is supplied along the heat-receiving plate 12 from a side opposite to the side face 14 to the heat sink 1, that is, supplied into a space 15 formed between the main surfaces 13 of the adjacent radiation fins 11. The cooling air F supplied into the space 15 circulates along the main surfaces 13 of the radiation fins 11 in the extending direction of the heat-receiving plate 12, and thereby cools the heat sink 1.

As shown in FIGS. 1 and 2, in the heat sink 1, the radiation fin 11 is provided with notched portions 16, Here, the term “notched portion” means a portion where rectangular shaped corners of the radiation fin are cut out and removed. Therefore, the “notched portion” is a region, corners of which are retracted from a virtual rectangle Re, as will be described later. As shown in FIG. 2, the notched portion 16 is configured such that a tip end 17 side corner of the radiation fin 11 is retracted inward in the main surface 13 direction of the radiation fin 11 with respect to the virtual rectangle Re formed of a side 20 of the radiation fin 11 on the heat-receiving unit side, a first side 21 extending from both ends 20a and 20b of the side 20 on the heat-receiving unit side in a direction orthogonal to the side 20 on the heat-receiving unit side and a second side 23 formed by extending a linear portion 22 on the side of the radiation fin 11 on the tip end 17 side facing the side 20 on the heat-receiving unit side to the first side 21.

In the heat sink 1, one notched portion 16 is provided at each of both corners on the tip end 17 side of the radiation fin 11. On the other hand, a central part on the tip end 17 side of the radiation fin 11 constitutes a linear portion 22 substantially parallel to the side 20 on the heat-receiving unit side and is not provided with any notched portion. Therefore, the central part on the tip end 17 side of the radiation fin 11 is higher than both corners provided with the notched portions 16.

The notch shape of the notched portion 16 is not particularly limited, but, for example, a C chamfer shape, an R chamfer shape, or a combination of a C chamfer shape and an R chamfer shape may be adopted. The notch shape of the notched portion 16 in the heat sink 1 is an R chamfer shape. Since the notch shape of the notched portion 16 is the R chamfer shape, it is possible to reliably reduce ventilation resistance of the cooling air F circulating between the radiation fins 11 of the heat sink 1 while reliably maintaining the excellent cooling performance. Note that the term “C chamfer shape” means the shape of the notched portion formed of a straight line in a side view and the term “R chamfer shape” means the shape of the notched portion formed of a curve in a side view.

The ratio of the dimension of the notched portion 16 in the first side 21 direction to the length of the first side 21 of the virtual rectangle Re (that is, the dimension from the side 20 on the heat-receiving unit side of the radiation fin 11 to the central part of the tip end 17 of the radiation fin 11 and corresponding to a height (H) of the radiation fin 11) is not particularly limited, but a lower limit value of the ratio is preferably 30%, more preferably 40% and particularly preferably 50% from the standpoint of more reliably reducing the ventilation resistance by more smoothly circulating the cooling air F between the radiation fins 11. On the other hand, the upper limit value of the ratio of the dimension is preferably 100% from the standpoint of more reliably reducing the ventilation resistance, more preferably 90% and particularly preferably 80% from the standpoint of securing the area of the radiation fin 11 and maintaining more excellent cooling performance. In the heat sink 1, the ratio of the dimension of the notched portion 16 is 100%.

The area ratio of the main surface 13 of the radiation fin 11 to the area of the virtual rectangle Re is not particularly limited, but the lower limit value of the ratio is preferably 50%, more preferably 60%, much more preferably 80%, and particularly preferably 85% from the standpoint of securing the area of the radiation fin 11 and maintaining more excellent cooling performance. On the other hand, the upper limit value of the area ratio is preferably 98%, more preferably 95% and particularly preferably 90% from the standpoint of more reliably reducing the ventilation resistance by more smoothly circulating the cooling air F between the radiation fins 11. In the heat sink 1, the area ratio of the notched portion 16 is approximately 90%.

The radius of curvature of the R chamfer shape of the notched portion 16 is, for example, preferably 10% to 100% of the height (H) of the radiation fin 11, more preferably 50% to 100%, and particularly preferably 80% to 100%. Although the dimension of the radius of curvature of the R chamfer shape of the notched portion 16 is not particularly limited, the lower limit value is preferably 5 mm, and particularly preferably 10 mm. On the other hand, the upper limit value of the radius of curvature of the R chamfer shape of the notched portion 16 can be changed as appropriate according to the size of the heat sink. Furthermore, the lower limit value and the upper limit value of the dimension of the radius of curvature of the R chamfer shape of the notched portion 16 can be changed according to the height (H) of the radiation fin 11. When the height (H) of the radiation fin 11 is assumed to be a mm, it is preferable that the dimension of the radius of curvature of the R chamfer shape of the notched portion 16 is α×0.5 or more and equal to or less than the dimension of the depth (width (W)) of the radiation fin 11. If the dimension of the radius of curvature of the R chamfer shape is within the above-described range, it is possible to efficiently reduce pressure loss of the cooling air F. Here, the “dimension of the depth (width (W)) of the fin” means the dimension of the radiation fin 11 in the direction parallel to the direction in which the cooling air F flows.

In the heat sink 1, the shape and dimension of the notched portion 16 are substantially the same for both corners of the radiation fin 11. The shape and dimension of the notched portion 16 are substantially the same among the respective radiation fins 11.

The notched portions 16 may be provided at both corners on the tip end 17 side of the radiation fin 11 or may be provided at either corner. However, from the standpoint of maintaining more excellent cooling performance by securing the area of the radiation fin 11, of both corners on the tip end 17 side of the radiation fin 11, it is preferable that a notched portion 15 is provided at a corner farther from a heating element 100 thermally connected to the heat-receiving unit 12.

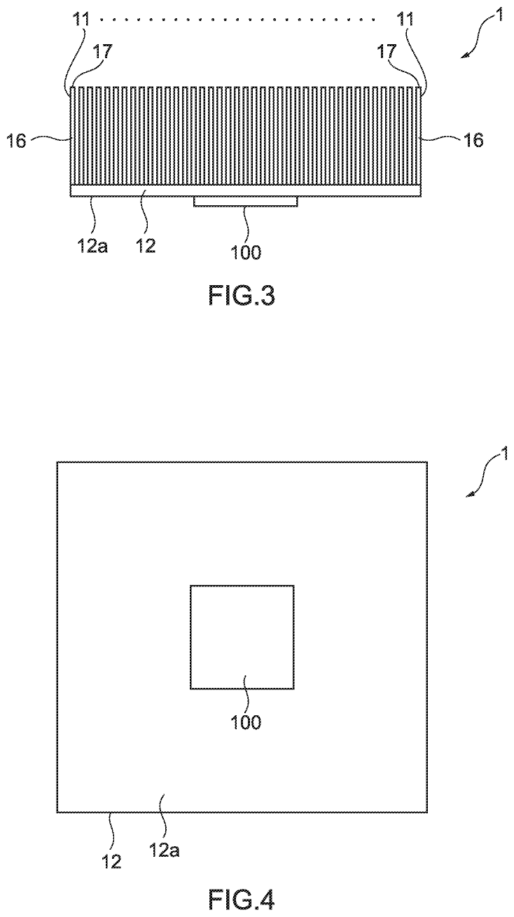

As shown in FIGS. 3 and 4, in the heat sink 1, the heating element 100 is thermally connected to the central part of the heat-receiving plate 12 to cool the heating element 100. The heating element 100 is thermally connected to a surface 12a of the heat-receiving plate 12 to which no radiation fin 11 is attached. Since the heating element 100 is attached to the central part of the heat-receiving plate 12, both corners on the tip end 17 side of the radiation fin 11 in the virtual rectangle Re have substantially the same distance from the heating element 100 for each radiation fin 11. When the heating element 100 is thermally connected to the center of the heat-receiving unit of the heat sink 1, it is preferable that the notched portions are provided at both corners on the tip end 17 side of the radiation fin 11.

The radiation fin 11 and the heat-receiving plate 12 are both metal materials having good thermal conductivity and made of aluminum, an aluminum alloy, copper, a copper alloy or the like.

Since the heat sink 1 includes the notched portion 15 where the tip end 17 side corner of the radiation fin 11 is retracted inward in the main surface 13 direction of the radiation fin 11 with respect to the virtual rectangle Re, ventilation resistance of the cooling air F circulating between the radiation fins 11 decreases and pressure loss of the cooling air F is reduced. Therefore, it is possible to prevent power consumption of the ventilating fan from increasing, which contributes to energy saving and allows the ventilating fan to be downsized, and thus the heat sink 1 can be mounted even in a small space. Furthermore, the heat sink 1 can reduce pressure loss of the cooling air F, and can thus demonstrate excellent cooling performance. While the tip end 17 side of the radiation fin 11 has less contribution to heat dissipation than the proximal end side close to the heat-receiving plate 12, since the notched portions 16 are provided on the tip end 17 side of the radiation fin 11, the heat sink 1 can maintain excellent cooling performance.

When the heat sink 1 is installed in wide flow paths through which the cooling air F circulates, if pressure loss of the cooling air F supplied between the radiation fins 11 of the heat sink 1 is reduced, the cooling air F is particularly smoothly supplied between the radiation fins 11.

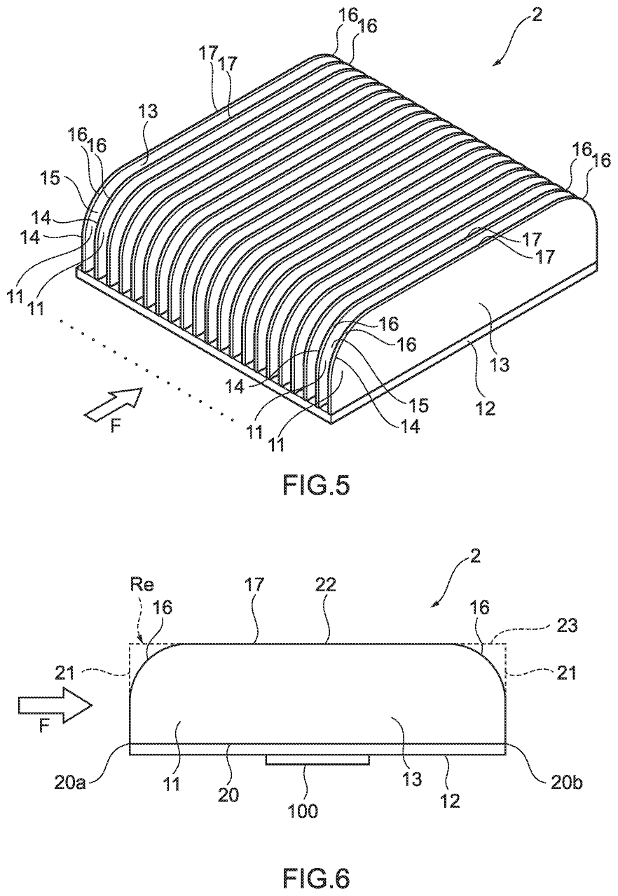

Thereafter, a heat sink according to a second exemplary embodiment of the present disclosure will be described using the accompanying drawings. Note that the same components as the components of the heat sink according to the first exemplary embodiment will be described, assigned the same reference numerals. While in the heat sink 1 according to the first exemplary embodiment, the ratio of the dimension of the notched portion 16 in the first side 21 direction to the length of the first side 21 of the virtual rectangle Re is 100%, instead of this, in a heat sink 2 according to the second exemplary embodiment, the ratio of the dimension of the notched portion 16 is approximately 50% as shown in FIGS. 5 and 6.

In the heat sink 2, the first side 21 of the virtual rectangle Re and the side face 14 of the radiation fin 11 overlap in approximately half of the region on the heat-receiving plate 12 side of the radiation fin 11, Therefore, the notched portion 16 is provided in approximately half of the region on the tip end 17 side of the radiation fin 11, whereas no notched portion is provided in approximately half of the region on the heat-receiving plate 12 side.

Thus, the ratio of the dimension of the notched portion 16 in the first side 21 direction to the length of the first side 21 of the virtual rectangle Re may be changed according to the capacity of the ventilating fan, an amount of heat of the heating element thermally connected to the heat sink or the like.

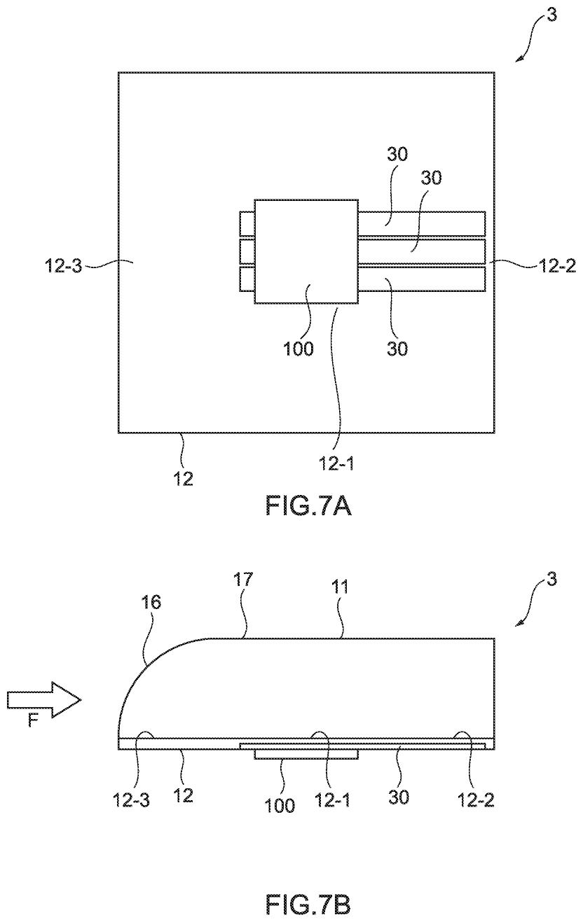

Thereafter, a heat sink according to a third exemplary embodiment of the present disclosure will be described using the accompanying drawings. Note that the same components as the components of the heat sink according to the first and second exemplary embodiments will be described, assigned the same reference numerals. As shown in FIGS. 7A and 7B, a heat sink 3 according to the third exemplary embodiment is configured such that the heat-receiving plate 12 of the heat sink 1 according to the first exemplary embodiment is further provided with heat pipes 30.

The heat sink 3 is provided with elongated tubular heat pipes 30 in an extending direction of the plane of the heat-receiving plate 12 to which the radiation fins 11 are attached. Therefore, a heat transport direction of the heat pipes 30 is substantially parallel to the extending direction of the plane of the heat-receiving plate 12. The heat pipes 30 in the heat sink 3 extend from a central part 12-1 to one edge part 12-2 of the heat-receiving plate 12, Therefore, no heat pipe 30 is attached to the heat-receiving plate 12 from the central part 12-1 to another edge part 12-3 of the heat-receiving plate 12. Note that the heating element 100 is thermally connected to the heat pipe 30 in the heat sink 3.

A container material of the heat pipes 30 is also made of a metal material similar to the metal material of the radiation fins and the heat-receiving plate 12, that is, for example, aluminum, an aluminum alloy, copper or a copper alloy. A fluid having adaptability to the container, which is a hermetically sealed container, is sealed in the heat pipes 30 in a decompressed state as an operating fluid. Examples of the operating fluid include water, alternative chlorofluorocarbon, perfluorocarbon, and cyclopentane.

In the heat sink 3, of both corners on the tip end 17 side of the radiation fins 11, the notched portion 16 is provided only at the corner farther from the heating element 100 and the heat pipes 30 thermally connected to the heat-receiving plate 12. That is, in the heat pipe 3, of both corners on the tip end 17 side of the radiation fin 11, no notched portion is provided at the corner closer to the one edge part 12-2 of the heat-receiving plate 12, whereas the notched portion 16 is provided at the corner closer to the other edge part 12-3 of the heat-receiving plate 12. Since the notched portion 16 is provided only at the corner farther from the heating element 100 and the heat pipes 30 thermally connected to the heat-receiving plate 12, it is possible to secure the fin area of the radiation fins 11 in the portion close to the heating element 100 and the heat pipes 30. Therefore, the heat sink 3 can also maintain excellent heat dissipation characteristics of the radiation fins 11. Furthermore, even when the notched portion 16 is formed at any one of both corners on the tip end 17 side of the radiation fin 11, ventilation resistance of the cooling air F circulating between the radiation fins 11 decreases, causing pressure loss of the cooling air F to decrease.

Thereafter, notched portions according to other embodiments caf the radiation fins used for the heat sink of the present disclosure will be described using the accompanying drawings.

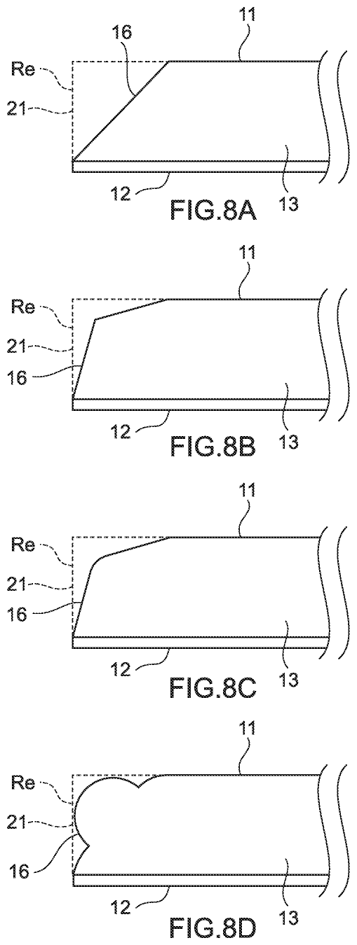

In the heat sink 1 according to the first exemplary embodiment, although the notched portions 16 provided in the radiation fins 11 have an R chamfer shape, instead of this, the notched portions 16 may have a C chamfer shape as shown in FIG. 8A. The notched portion 16 may have a combination of a plurality of (two in the drawing) different C chamfer shapes as shown in FIG. 8B. Furthermore, the notched portion 16 may have a combination of a C chamfer shape and an R chamfer shape as shown in FIG. 8C, In FIG. 8C, one R chamfer shape is formed between two different C chamfer shapes. Furthermore, the notched portion 16 may have a combination of a plurality of (three in the drawing) different R chamfer shapes as shown in FIG. 8D.

In all the shapes of the notched portions 16 shown in FIGS. 8A to 8D, although the ratio of the dimension of the notched portion 16 in the first side 21 direction to the length of the first side 21 of the virtual rectangle Re is not particularly limited, the lower limit value of the ratio is preferably 30%, more preferably 40% and particularly preferably 50% from the standpoint of more reliably reducing ventilation resistance by more smoothly circulating the cooling air F between the radiation fins 11. On the other hand, the upper limit value of the ratio of the dimension is preferably 100% from the standpoint of more reliably reducing the ventilation resistance, more preferably 90% and particularly preferably 80% from the standpoint of maintaining more excellent cooling performance by securing the area of the radiation fins 11. Note that in FIGS. 8A to 8D, the ratio of the dimension of the notched portion 16 is 100% in all cases.

In all the shapes of the notched portions 16 shown in FIGS. 8A to 8D, although the area ratio of the main surface 13 of the radiation fins 11 to the area of the virtual rectangle Re is not particularly limited, the lowerlimit value of the ratio s preferably 80%, and particularly preferably 85% from the standpoint of maintaining more excellent cooling performance by securing the area of the radiation fins 11, On the other hand, the upper limit value of the area ratio is preferably 98%, more preferably 95%, and particularly preferably 90% from the standpoint of more reliably reducing ventilation resistance by more smoothly circulating the cooling air F between the radiation fins 11.

Thereafter, other exemplary embodiments of the present disclosure will be described. In the heat sink of each of the above exemplary embodiments, although thin, flat plate-shaped radiation fins are provided upright on the heat-receiving plate, the aspect of the heat sink is not particularly limited, but, for example, U-shaped members in a side view may be arranged in parallel and connected to form a heat sink. In this case, the heat-receiving plate, which is a member separate from the U-shaped member in a side view, need not be provided in the heat sink.

In the heat sink of each of the above exemplary embodiments, since a dimension of each radiation fin in the width direction and a dimension in the height direction are different, for the notched portion, a virtual rectangle was formed of the side of the radiation fin on the heat-receiving unit side, the first side and the second side. Instead of this, when the dimension of the radiation fin in the width direction is equal to the dimension in the height direction, and the length of the first side equal to the length of the side on the heat-receiving unit side, a virtual square is formed instead of a virtual rectangle.

In the heat sink of each of the above exemplary embodiments, although both corners of each radiation fin have substantially the same shape and dimension of the notched portion, instead of this, both corners may have different shapes and dimensions of the notched portion. For example, when the heating element is thermally connected to the peripheral edge of the heat-receiving plate on the upstream side of the cooling air, a smaller notched portion may be provided at one corner located relatively near the heating element of both corners of the radiation fin to secure the fin area and maintain excellent heat dissipation characteristics and a larger notched portion may be provided at the other corner located relatively far from the heating element to reduce pressure loss of the cooling air.

In the heat sink of each of the above exemplary embodiments, although the shape and dimension of the notched portions are substantially the same among the respective radiation fins, instead of this, the notched portions may have different shapes and/or dimensions depending on the position of the heat-receiving plate on which the radiation fins are provided upright. For example, when the heating element is thermally connected to the peripheral edge of the heat-receiving plate, a smaller notched portion may be provided for radiation fins located relatively close to the heating element to maintain excellent heat dissipation characteristics by securing the fin area and a larger notched portion may be provided for radiation fins located relatively far from the heating element to reduce pressure loss of the cooling air.

### EXAMPLES

Thereafter, an example of the present disclosure will be described, but the present disclosure is not limited to the example without departing from the spirit of the present disclosure.

### Example

The heat sink according to the first exemplary embodiment was used as a heat sink in an example. In correspondence with the fact that a width of a flat plate-shaped heat-receiving plate (material: copper) is 95 mm and a dimension from one end to another end of the heat-receiving plate is 90 mm, a number of radiation fins (material: copper) having a width of 95 mm shown in Table 1 below were attached from one end to the other end of the heat-receiving plate at a radiation fin pitch shown in Table 1 below. Note that the thickness of the heat-receiving plate was assumed to be 3 mm. Moreover, in correspondence with the fact that the height of the radiation fin is 25 mm, the radius of curvature R of the notched portion, which is an R chamfer shape was assumed to be 25 mm. The heating element, which is an object to be cooled was connected to the central part of the heat-receiving plate.

### Comparative Example

As a heat sink in a comparative example, a heat sink having a structure similar to the structure in the example except that no notched portion is provided in the radiation fins was used. Therefore, in the heat sink in the comparative example, rectangular radiation fins having a width of 95 mm×a height of 25 mm were attached to the heat-receiving plate.

Test conditions in the example and the comparative example are as follows:

Amount of cooling air: 10 CFM

Cooling air temperature: 20° C.

Amount of heat input from heating element: 90 W

A rising temperature of the heating element was calculated by measuring a surface temperature of the heating element after testing using a thermocouple according to an expression: [rising temperature of heating element=surface temperature of heating element after testing−ambient temperature].

The pressure loss of the cooling air was calculated by assuming a place 30 mm from the heat sink horizontal to a wind direction toward the windward direction as an inlet pressure and assuming a place 30 mm from the heat sink horizontal to a wind direction toward the leeward direction as an outlet pressure according to an expression: [inlet pressure−outlet pressure]

The test results of the example and the comparative example are shown in Table 1 below.

TABLE 1

| | Radi- | Number | Rising | Temperature | |
|---|---|---|---|---|---|
| | ation | of radi- | temperature | rising rate of | Pressure |
| | fin | ation | of heating | heating | loss of |
| | pitch | fins | element | element | cooling air |
| | [mm] | [pcs] | [° C.] | [° C./W] | [inchH20] |
| Example | 1.1 | 84 | 30.8 | 0.325 | 0.232 |
| Comparative | 1.1 | 84 | 30.8 | 0.325 | 0.258 |
| example | | | | | |

It is observed from Table 1 that in the example where notched portions are provided in the radiation fin similar to the comparative example where no notched portions are provided in the radiation fin, it was possible to suppress a temperature rise in the heating element. Furthermore, in the example, it was further possible to reduce pressure loss of the cooling air circulating through the heat sink. On the other hand, in the comparative example where no notched portion was provided in the radiation fin, it was not possible to reduce pressure loss of the cooling air circulating through the heat sink as much as in the example.

The heat sink of the present disclosure can reduce pressure loss by preventing an increase in ventilation resistance of the cooling air while obtaining excellent cooling performance, and so the heat sink of the present disclosure exhibits a high utility value in fields where forced air cooling is performed using ventilating fans or the like.

What is claimed is:

1. A heat sink comprising a radiation fin extending in a vertical direction from a heat-receiving unit, wherein
the radiation fin comprises a notched portion in which a tip end side corner of the radiation fin is retracted inward in a main surface direction of the radiation fin with respect to a virtual rectangle or a virtual square formed of a side of the radiation fin on the heat-receiving unit side viewed from the main surface side, a first side extending from both ends of the side on the heat-receiving unit side in a direction orthogonal to the side on the heat-receiving unit side and a second side formed by extending a linear portion on the side of the radiation fin on a tip end side facing the side on the heat-receiving unit side to the first side.

2. The heat sink according to claim 1, wherein the notched portion has a C chamfer shape, an R chamfer shape or a combination of a C chamfer shape and an R chamfer shape.

3. The heat sink according to claim 1, wherein a ratio of a dimension of the notched portion in the first side direction to a length of the first side of the virtual rectangle or the virtual square is 30% to 100%.

4. The heat sink according to claim 2, wherein a ratio of a dimension of the notched portion in the first side direction to a length of the first side of the virtual rectangle or the virtual square is 30% to 100%.

5. The heat sink according to claim 1, wherein an area ratio of the main surface of the radiation fin to an area of the virtual rectangle or the virtual square is 50% to 98%.

6. The heat sink according to claim 2, wherein an area ratio of the main surface of the radiation fin to an area of the virtual rectangle or the virtual square is 50% to 98%.

7. The heat sink according to claim 3, wherein an area ratio of the main surface of the radiation fin to an area of the virtual rectangle or the virtual square is 50% to 98%.

8. The heat sink according to claim 4, wherein an area ratio of the main surface of the radiation fin to an area of the virtual rectangle or the virtual square is 50% to 98%.

9. The heat sink according to claim 1, wherein the notched portion has an R chamfer shape.

10. The heat sink according to claim 3, wherein the notched portion has an R chamfer shape.

11. The heat sink according to claim 9, wherein a radius of curvature of the R chamfer shape is 5 mm or more.

12. The heat sink according to claim 10, wherein a radius of curvature of the R chamfer shape is 5 mm or more.

13. The heat sink according to claim 1, wherein the notched portions are provided at both corners on the tip end side of the radiation fin.

14. The heat sink according to claim 1, wherein the notched portion is provided at a corner farther from a heating element thermally connected to the heat-receiving unit of both corners on the tip end side of the radiation fin.

15. The heat sink according to claim 2, wherein the notched portion is provided at a corner farther from a heating element thermally connected to the heat-receiving unit of both corners on the tip end side of the radiation fin.

16. The heat sink according to claim 3, wherein the notched portion is provided at a corner farther from a heating element thermally connected to the heat-receiving unit of both corners on the tip end side of the radiation fin.

17. The heat sink according to claim 5, wherein the notched portion is provided at a corner farther from a heating element thermally connected to the heat-receiving unit of both corners on the tip end side of the radiation fin.

18. The heat sink according to claim 1, further comprising a heat-receiving plate, wherein the radiation fin extends in the vertical direction from the heat-receiving plate.

19. The heat sink according to claim 1, further comprising a heat pipe.

20. The heat sink according to claim 19, wherein the notched portion is provided at a corner farther from a heating element and the heat pipe thermally connected to the heat-receiving unit of both corners on the tip end side of the radiation fin.
